(19) United States
(12) Patent Application Publication
(10) Pub. No.: US 2026/0271460 A1
(43) Pub. Date: Sep. 10, 2026

(54) LIGHT-EMITTING ELEMENT AND DISPLAY DEVICE

(71) Applicant: Takahiro ADACHI

(72) Inventor: Takahiro ADACHI

(21) Appl. No.: 19/137,788

(22) PCT Filed: Dec. 29, 2022
(86) PCT No.: PCT/JP2022/048696

§ 371 Date: Jun. 11, 2025

(51) Int. Cl. H10H 29/80; H10H 20/812; H10H 29/01; H10H 29/14

(52) U.S. Cl. CPC H10H 29/8421; H10H 20/812; H10H 29/011; H10H 29/034; H10H 29/142

(57) ABSTRACT

A first functional layer (F1) of a light-emitting element (ES) according to the present disclosure has: a first portion (P1); and a second portion (P2) positioned outside the first portion (P1) of the first functional layer (F1). The second portion (P2) is thicker than the first portion (P1).

### TECHNICAL FIELD The present disclosure relates to a light-emitting element, a display device, and a method for producing the light-emitting element.

### BACKGROUND ART

Patent Document 1 discloses a light-emitting element provided with a reflective layer on a side surface of a partition wall.

### CITATION LIST

### Patent Literature

[Patent Document 1] Japanese Unexamined Patent Application Publication No. 2010-009793 (Published on Jan. 14, 2010)

### SUMMARY

### Technical Problem

However, when a wide reflective layer is provided on, for example, the side surface of the partition wall as described in Patent Document 1, the light is highly likely to be scattered and/or reflected unintentionally, and the light-emitting element could suffer deterioration in quality.

### Solution to Problem

A light-emitting element according to an aspect of the present disclosure includes: a bank; a first light reflective layer positioned above the bank; and a first functional layer positioned above the first reflective layer. The first functional layer has: a first portion; and a second portion positioned outside the first portion of the first functional layer. The second portion is thicker than the first portion.

A method for producing a light-emitting element according to an aspect of the present disclosure includes: a step of forming a bank; a step of forming a light reflective layer above the bank; and a step of forming a functional layer above the light reflective layer. At the step of forming the functional layer, the first functional layer is formed to have: a first portion; and a second portion positioned outside the first portion of the first functional layer. The second portion is thicker than the first portion.

### Advantageous Effect of Disclosure

The present disclosure can provide a light-emitting element with high quality.

### BRIEF DESCRIPTION OF DRAWINGS

FIG. 1 is a conceptual diagram illustrating an exemplary configuration of a display device according to an embodiment of the present disclosure.

FIG. 2 is a cross-sectional view illustrating an exemplary configuration of the display device according to an embodiment of the present disclosure.

FIG. 3 is a plan view illustrating an exemplary configuration of the display device according to an embodiment of the present disclosure. FIG. 4 is a plan view illustrating an exemplary configuration of the display device according to an embodiment of the present disclosure.

FIG. 5 is a plan view illustrating an exemplary configuration of the display device according to an embodiment of the present disclosure.

FIG. 6 is a plan view illustrating an exemplary configuration of the display device according to an embodiment of the present disclosure.

FIG. 7 is a flowchart showing an exemplary method for producing a light-emitting element illustrated in FIG. 2.

FIG. 8 illustrates cross-sectional views showing an exemplary method for producing the light-emitting element illustrated in FIG. 2.

FIG. 9 illustrates cross-sectional views showing another exemplary step of forming a reflective film.

FIG. 10 illustrates cross-sectional views showing yet another exemplary step of forming a reflective film.

FIG. 11 illustrates cross-sectional views showing an exemplary step of forming a first functional layer.

FIG. 12 is a cross-sectional view illustrating an exemplary configuration of the display device according to an embodiment of the present disclosure.

FIG. 13 is a flowchart showing an exemplary method for producing a light-emitting element illustrated in FIG. 12.

FIG. 14 illustrates cross-sectional views showing an exemplary method for producing the light-emitting element illustrated in FIG. 12.

FIG. 15 is a cross-sectional view illustrating an exemplary configuration of the display device according to an embodiment of the present disclosure.

FIG. 16 is a cross-sectional view illustrating an exemplary configuration of the display device according to an embodiment of the present disclosure.

FIG. 17 is a cross-sectional view illustrating an exemplary configuration of the display device according to an embodiment of the present disclosure.

FIG. 18 is a cross-sectional view illustrating an exemplary configuration of the display device according to an embodiment of the present disclosure.

FIG. 19 is a cross-sectional view illustrating an exemplary configuration of the display device according to an embodiment of the present disclosure.

FIG. 20 is a plan view illustrating an exemplary configuration of the display device according to an embodiment of the present disclosure.

FIG. 21 is a cross-sectional view taken along line A-A of FIG. 20.

FIG. 22 is a plan view illustrating a modification of a configuration of the display device according to an embodiment of the present disclosure.

FIG. 23 is a cross-sectional view taken along line B-B of FIG. 22.

FIG. 24 is a plan view illustrating a modification of a configuration of the display device according to an embodiment of the present disclosure.

FIG. 25 is a cross-sectional view of a light-emitting element according to the present disclosure.

### DESCRIPTION OF EMBODIMENTS

### First Embodiment

### Display Device

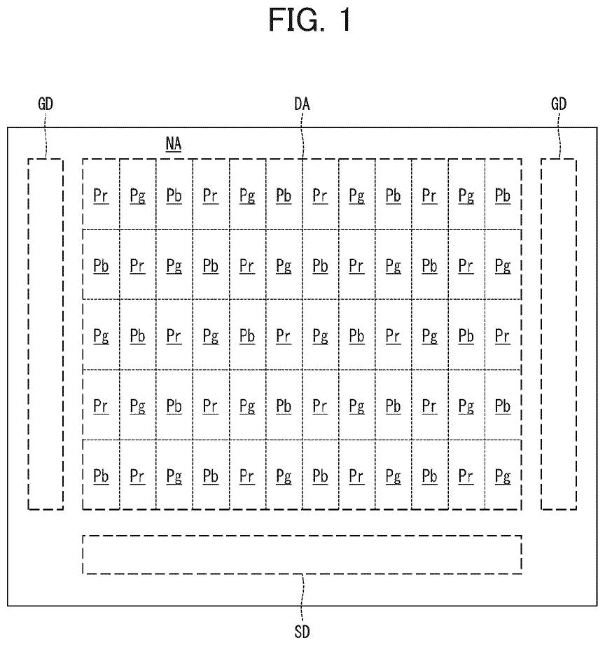

FIG. 1 is a conceptual diagram illustrating an exemplary configuration of a display device according to an embodiment of the present disclosure. As illustrated in FIG. 1, a display device 1 includes: a display region DA; and a picture-frame region NA surrounding the display region DA.

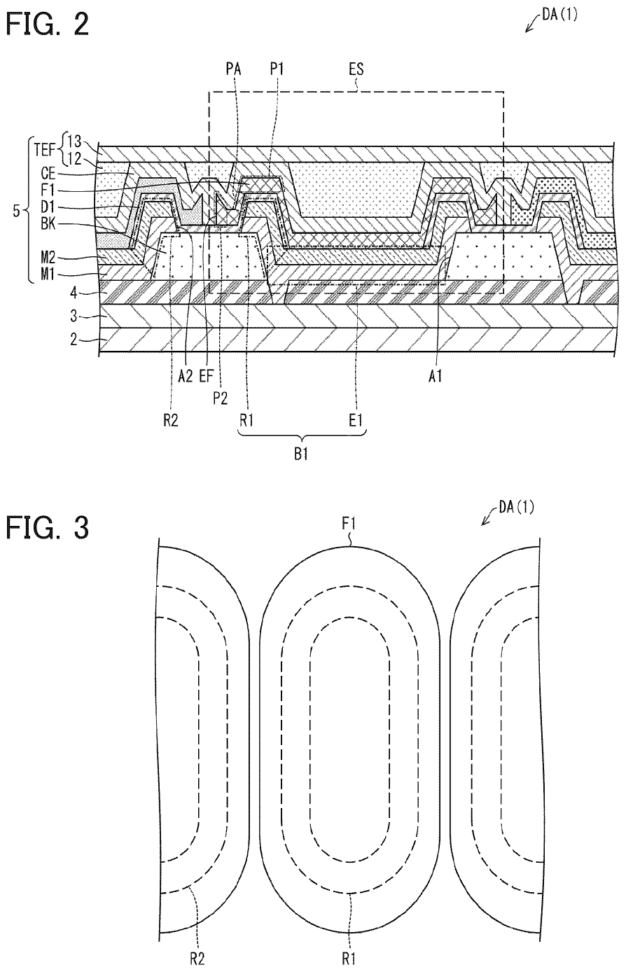

The display region DA is provided with: red subpixels Pr each including a light-emitting element ES (see FIG. 2) that emits light in red; green subpixels Pg each including a light-emitting element ES that emits light in green; and blue subpixels Pb each including a light-emitting element ES that emits light in blue. Hereinafter, the red subpixels Pr, the green subpixels Pg, and the blue subpixels Pb are collectively referred to as “subpixels P”. FIG. 1 shows an example in which the subpixels P are arranged obliquely. However, the subpixels P may be arranged in any given manner such as a PenTile Matrix or a stripe. Each of the subpixels P includes: one or more light-emitting elements ES according to the present disclosure; and a pixel circuit for controlling the one or more light-emitting elements ES.

The picture-frame region NA is provided with: a gate driver GD; a source driver SD, a wire (not shown) for connecting the display region DA with the gate driver GD and the source driver SD; and a wire and a terminal (not shown) for supplying power and signals to the gate driver GD and the source driver SD.

### Configuration of Display Region in Cross-Section

FIG. 2 is a cross-sectional view illustrating an exemplary configuration of the display device according to an embodiment of the present disclosure. As illustrated in FIG. 2, the display device 1 according to the present disclosure includes: a support substrate 2; a circuit layer 3 formed on the support substrate 2 and including a pixel circuit; a planarization film 4 formed on the circuit layer 3; and a light-emitting-element layer 5 formed on the planarization film 4 and including a light-emitting element ES. The display device 1 may include a plurality of the light-emitting elements ES.

The light-emitting element ES according to the present disclosure includes: a bank BK; a first light reflective layer R1 positioned above the bank BK; and a first functional layer F1 positioned above the first light reflective layer R1. The first functional layer F1 has: a first portion P1, PA positioned above the bank BK; and a second portion P2 positioned above the bank BK and outside the first portion of the first functional layer F1. The second portion P2 is thicker than the first portion P1, PA. The second portion P2 may project upwards with respect to the first portion P1, PA.

The first portion P1, PA may include: a first portion P1 positioned above the first light reflective layer R1; and a first portion PA positioned outside the first light reflective layer R1 of the first functional layer F1. The second portion P2 is thicker than one of, or both, the first portion P1 and the first portion PA. In the present disclosure, the statement “outside a certain layer” means close to an outer periphery of the layer. Hence, the second portion P2 is closer to an outer periphery of the first functional layer F1 than the first portion P1 and PA. Furthermore, the first portion PA is closer to the outer periphery of the first functional layer F1 than the first portion P1.

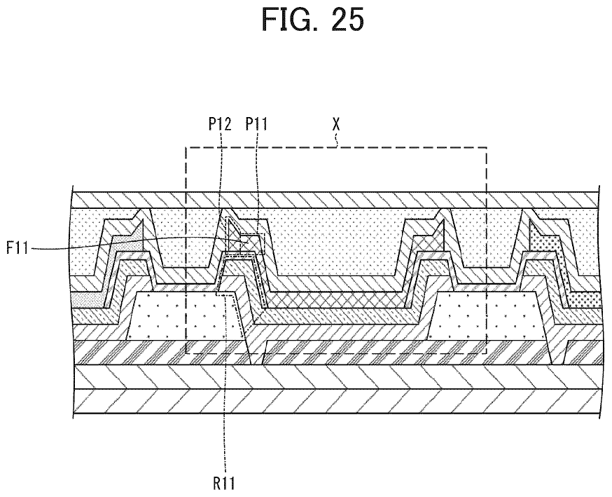

FIG. 25 is a cross-sectional view of a light-emitting element according to the present disclosure. A light-emitting element X illustrated in FIG. 25 includes: a functional layer F11; and a light reflective layer R11. The functional layer F11 has: a first portion P11 positioned above the light reflective layer R11; and a second portion P12 positioned above the light reflective layer R11 and thicker than the first portion P1. The first portion P1 is, for example, formed to project upwards. The first portion and the second portion may or may not be positioned above the bank. In FIG. 25, even if the light reflective layer R11 is formed above the bank BK, the functional layer F11 has an end portion formed thick so that guided light in the functional layer F11 is likely to gather at the end portion. Such a feature can prevent unintended scattering and reflection of the light, and further stabilize quality of the light-emitting element. Specifically, the quality of the light-emitting element includes, for example, reducing variations in viewing angle characteristics caused by uneven distribution of light in a pixel. The feature can further stabilize such quality of the light-emitting element.

As to the configuration illustrated in FIG. 2, the second portion P2 does not overlap with the first light reflective layer R1 in a plan view. Hence, the first light reflective layer R1 is less likely to reflect light scattered by the second portion P2. Thus, the light reflected by the first light reflective layer R1 appears more orderly than the light reflected by the light reflective layer R11 in FIG. 25. Such a feature can reduce an influence of the light scattered by the second portion P2, such that the first functional layer F1 and the first light reflective layer R1 can act relatively effectively. Furthermore, the second portion P2 is positioned in a recess formed between an upper face of the bank BK and an end face of the first light reflective layer R1. Such a feature can further reduce the scattering of the light collected at the end portion of the functional layer F11, and stabilize the quality of the light-emitting element. Hence, the configuration illustrated in FIG. 2 can reduce deterioration in the quality of the light-emitting element ES. Furthermore, the stabilized quality of the light-emitting element can reduce deterioration in display quality of a display device including the light-emitting element. Moreover, for example, the display quality of the display device is affected by optical crosstalk. The configuration in FIG. 2 can control the optical crosstalk more readily and reduce deterioration in the display quality. In addition, as described above, the end portion of the functional layer F11 is formed in a recess. Such a feature can keep the functional layer F11 from peeling off the end portion and deforming.

The bank BK, which is an insulator, may be formed of a resin or a photosensitive resin. The first light reflective layer R1 may include a film reflective to light. The film may be a thin film made of, for example, silver (Ag), a AgMg alloy containing silver and magnesium (Mg), or aluminum (Al). The first light reflective layer R1 may include a plurality of layers, and may have, for example, a first film M1 reflective to light and a second film M2 positioned above the first film M1 and transparent to light. The first functional layer F1, which is any given functional layer, may be, for example, any of a hole injection layer, a hole transport layer, an electron-shielding layer, a light-emitting layer, a hole-shielding layer, an electron transport layer, and an electron injection layer. The light-emitting element ES may include as appropriate a functional layer other than the first functional layer F1.

The hole injection layer and the hole transport layer contain a hole transport material and/or a photosensitive hole transport material. Examples of the hole transport material include NiO, Cul, CuzO, CoO, Cr₂O₃, and CuAlS₂. Examples of the photosensitive hole transport material include OTPD, QUPD, and X-F6-TAPC. The electron transport layer and the electron injection layer contain such substances as ZnO, ZnS, ZrO, MgZnO, AlZnO, and TiO₂.

The light-emitting layer contains an inorganic light-emitting material such as quantum dots or an organic light-emitting material. The quantum dots emit light when electrons and holes recombine together. Each of the quantum dots may be a core quantum dot, a core-shell quantum dot, or a core-multishell quantum dot. Examples of a core-shell material of the core-shell quantum dots include CdSe-CdS, CdSe-ZnS, CdTe-CdS, InP-ZnS, GaP-ZnS, Si-ZnS, InN-GaN, InP-CdSSe, InP-ZnSeTe, GaInP-ZnSe, GaInP-ZnS, Si-AIP, InP-ZnSTe, GaInP-ZnSTe, and GaInP-ZnSSe.

Furthermore, the light-emitting layer may contain a plurality of quantum dots and a matrix holding the quantum dots. The statement “holding the quantum dots” means that a region sandwiched between two adjacent quantum dots is at least partially filled with a matrix. The matrix may be formed as, for example, a continuous film. The continuous film means a film not separated with a material other than the material forming the continuous film. The continuous film may be a seamless single film formed by chemical bonding of a material contained in the matrix. Furthermore, the continuous film may be formed as a film having an area of 1000 nm 2 or more in a plane direction perpendicular to the film thickness direction. The matrix may be, for example, an inorganic matrix formed mainly of an inorganic compound. The inorganic compound may be, for example, a metal sulfide such as ZnS.

The second portion P2 does not have to overlap with the first light reflective layer R1 in a plan view, and may serve as an outer peripheral portion of the first functional layer F1. In the plan view, the second portion P2 may have an end face EF not overlapping with the first light reflective layer R1.

A first opening A1 is formed in the bank BK. The light-emitting element ES includes an electrode E1 overlapping with the first opening A1 in a plan view. The electrode E1 may be an electrode shaped into an island shape and provided to one subpixel P. The light-emitting element ES may include a counter electrode CE facing the electrode E1. The first functional layer F1 may be positioned between the electrode E1 and the counter electrode CE. The counter electrode CE may be formed of: silver nanowires (AgNWs) or a thin silver film; and a transparent conductive film. The counter electrode CE may be a common electrode provided across the plurality of subpixels P. The first light reflective layer R1 partially or entirely covers a sidewall of the first opening A1. The first light reflective layer R1 may partially cover an upper face of the bank BK.

The electrode E1 may be a reflective electrode reflective to light, and may contain, for example, a thin film made of, for example, silver, a AgMg alloy, or aluminum. The electrode E1 may include a plurality of layers, and may have, for example, the first film M1 reflective to light and the second film M2 positioned above the first film M1 and transparent to light. The electrode E1 may be designed to suit an optical cavity of the light-emitting element ES. For the sake of simplicity, the present disclosure describes an example in which the electrode E1 is an anode and the counter electrode CE is a cathode. The present disclosure shall not be limited to such an example. Another example in which the electrode E1 is a cathode and the counter electrode CE is an anode is also included in the scope of the present disclosure.

The electrode E1 may be in contact with, and electrically connected to, the first light reflective layer R1. The electrode E1 may have one or more layers shared with the first light reflective layer R1. Whereas, the whole electrode E1 may be formed of the same layer as the entire first light reflective layer R1. If the electrode E1 is formed of the same layer as the first light reflective layer R1, the electrode E1 and the first light reflective layer R1 may be beneficially formed at the same step. The electrode E1 and the first light reflective layer R1 may be formed into a single piece. The light-emitting element ES may have one reflective film B1 including the electrode E1 and the first light reflective layer R1.

In the present disclosure, the term “the same layer” means that a constituent feature is formed at the same process (a film-depositing step) and of substantially the same material. The substantially same material includes the same material subjected to a treatment such as doping or irradiating with light. The term “below” means that a constituent feature is formed in a previous process before a comparative layer, and the term “above” means that a constituent feature is formed in a successive process after a comparative layer. The term “a separate layer” includes the layer below, and the layer above, the comparative layer.

The light-emitting element ES may further include an insulating layer D1 positioned between the first light reflective layer R1 and the first functional layer F1. The insulating layer D1 may be an inorganic insulating layer containing an inorganic insulator such as silicon oxide and silicon nitride. The insulating layer D1, which covers the first light reflective layer R1, can insulate the first light reflective layer R1 from the first functional layer F1. The light-emitting element ES may further include a sealing layer TEF covering the counter electrode CE.

The light-emitting element ES may further include a first photorefractive layer 12 positioned above the first functional layer F1. The first photorefractive layer 12 may be positioned above the counter electrode CE and included in the sealing layer TEF. For example, the first photorefractive layer 12 may be an organic resin film, and the sealing layer TEF may include the first photorefractive layer 12 and an inorganic film 13 above the first photorefractive layer 12.

A refractive index of the first photorefractive layer 12 may be greater than a refractive index of the external environment (usually the atmosphere). In this case, light traveling obliquely from the first photorefractive layer 12 toward the external environment is reflected off a boundary surface, and is likely to return to the inside of the light-emitting element ES. A portion of the returning light is multiply reflected inside the light-emitting element ES, and emitted from the first photorefractive layer 12 in a front direction toward the external environment. A structure suitable for improving the front luminance of the light-emitting element ES can be determined from optical calculations.

The first photorefractive layer 12 may be formed thin above an upper face of the bank BK. Preferably, in a plan view, the first photorefractive layer 12 may be formed not to overlap with at least a portion of the upper face of the bank BK. The first photorefractive layer 12 is discontinuous above the bank BK. Such a feature can reduce optical crosstalk caused by the first photorefractive layer 12.

The display device 1 may further include a second light reflective layer R2 positioned above the bank BK. The first light reflective layer R1 and the second light reflective layer R2 may form a second opening A2. In a plan view, the second portion P2 of the first functional layer F1 and the second opening A2 may overlap with each other. The second opening A2 is a recess formed between the first light reflective layer R1 and the second light reflective layer R2. In other words, in a plan view, the second portion P2 may be positioned between the first light reflective layer R1 and the second light reflective layer R2.

The second light reflective layer R2 may include a film reflective to light, and may be formed of a plurality of layers. An outer shape of the second light reflective layer R2 may or may not be similar to an outer shape of the first light reflective layer R1. The second light reflective layer R2 may be electrically separated from the first light reflective layer R1. The second light reflective layer R2 may be formed of the same layer as, or a separate layer from, the first light reflective layer R1. Each of the first light reflective layer R1 and the second light reflective layer R2 may be formed on a pixel-by-pixel basis. The insulating layer D1 can insulate the first light reflective layer R1 from the second light reflective layer R2.

### First Configuration of Display Region in Plan View

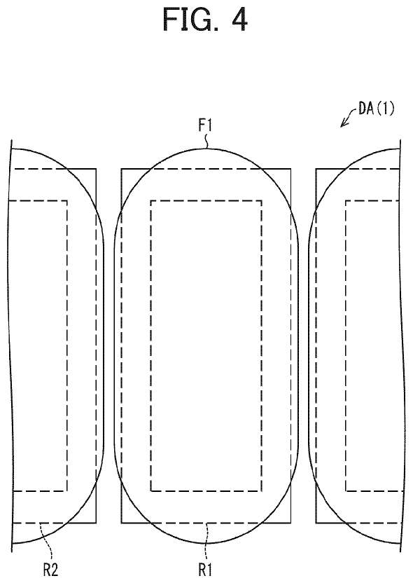

FIGS. 3 and 4 are plan views each illustrating an exemplary configuration of the display device according to an embodiment of the present disclosure. As illustrated in FIG. 3, in a plan view, the outer shape of the first light reflective layer R1 may be similar to an outer shape of the first functional layer F1. As illustrated in FIG. 4, in a plan view, the outer shape of the first light reflective layer R1 does not have to be similar to the outer shape of the first functional layer F1. For example, the first light reflective layer R1 may be angular, and the first functional layer F1 may be rounded. For example, the first light reflective layer R1 may be shaped into a bellows shape, and the first functional layer F1 does not have to be shaped into a bellows shape. The bellows shape beneficially improves contact by dispersing stress. Hence, the first light reflective layer R1 having the bellows shape is in intimate contact with a layer below. When a layer above the first light reflective layer R1 is formed, the first light reflective layer R1 is less likely to peel off the layer. As illustrated in FIGS. 3 and 4, in a plan view, the first light reflective layer R1 may be shaped to surround a portion of the first functional layer F1.

### Second Configuration of Display Region in Plan View

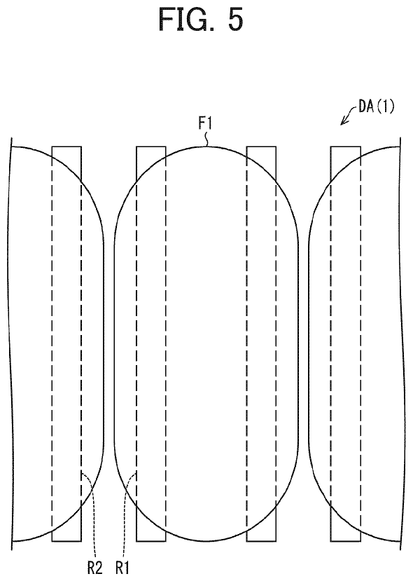

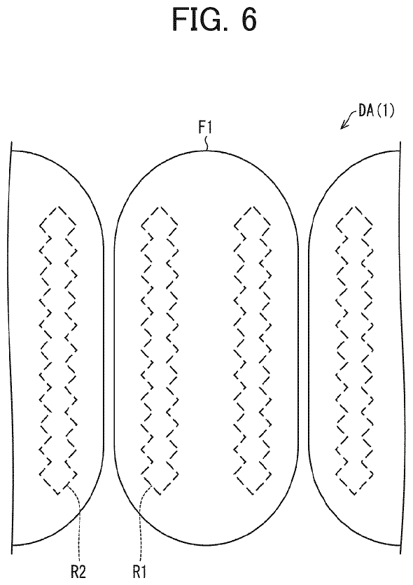

FIGS. 5 and 6 are plan views each illustrating an exemplary configuration of the display device according to an embodiment of the present disclosure. As illustrated in FIGS. 5 and 6, in a plan view, the first light reflective layer R1 may be shaped not to surround the first functional layer F1. As illustrated in FIG. 6, in a plan view, the first light reflective layer R1 may be shaped into a bellows shape.

### Method for Producing Light-Emitting Element

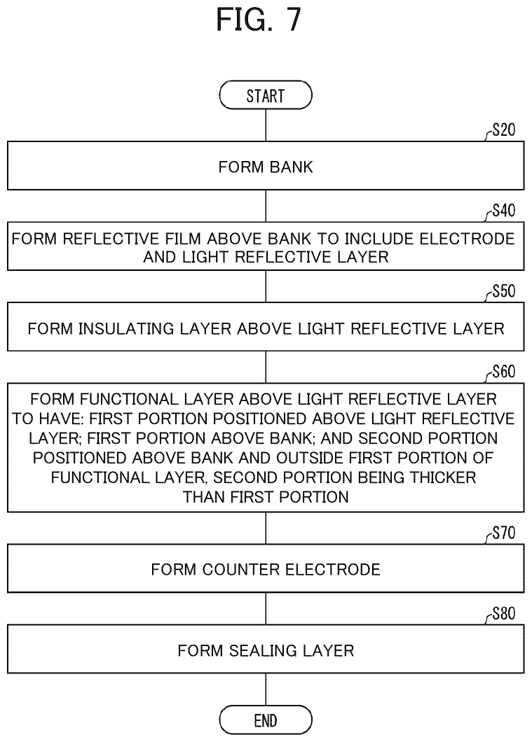

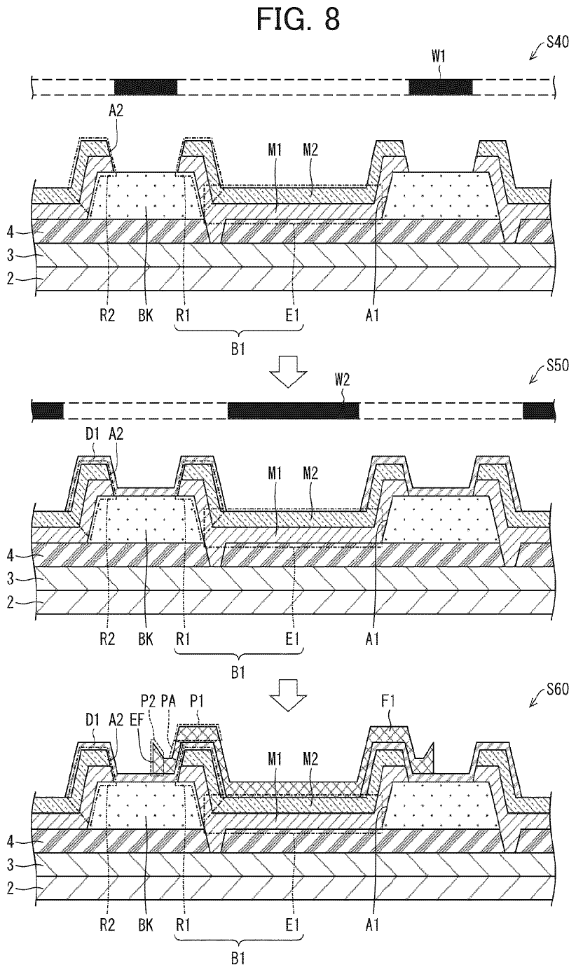

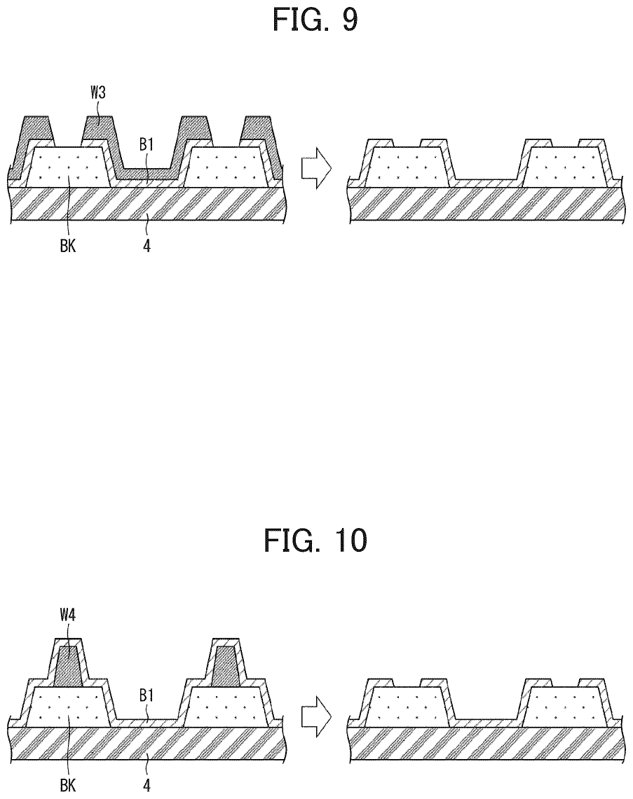

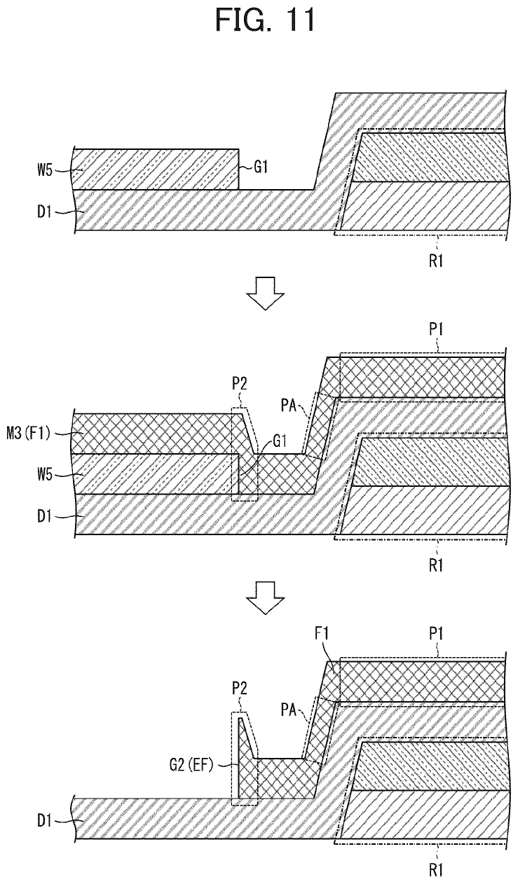

FIG. 7 is a flowchart showing an exemplary method for producing the light-emitting element illustrated in FIG. 2. FIG. 8 illustrates cross-sectional views showing an exemplary method for producing the light-emitting element illustrated in FIG. 2. FIGS. 9 and 10 illustrate cross-sectional views each showing another exemplary step of forming the reflective film. FIG. 11 illustrates cross-sectional views showing an exemplary step of forming the first functional layer.

As illustrated in FIGS. 7 and 8, the bank BK is formed on the planarization film 4 (Step S20). Above the bank BK, the reflective film B1 is formed to include the electrode E1 and the first light reflective layer R1 (Step S40). Subsequently, the insulating layer D1 is formed above the first light reflective layer R1 (Step S50). Above the first light reflective layer R1, the first functional layer F1 is formed (Step S60). Then, the counter electrode CE is formed (Step S70), and the sealing layer TEF is formed (Step S80). Moreover, between Step S50 and Step S70, a functional layer other than the first functional layer F1 is formed as appropriate.

At the step of forming the reflective film B1 (Step S40), the reflective film B1 may be formed by vapor deposition or sputtering. If the reflective film B1 is formed of a plurality of layers, each of the layers may be sequentially formed by vapor deposition or sputtering. In forming the reflective film B1, as illustrated in FIG. 8, the reflective film B1 may be patterned using a mask W1. Alternatively, as illustrated in FIG. 9, the reflective film B1 may be etched to be patterned. Specifically, a photoresist W3 may be formed on the reflective film B1 and patterned to serve as a template. The patterned reflective film B1 may be etched with an acidic solution and patterned. After the etching, the photoresist W3 is removed using a solvent. Alternatively, as illustrated in FIG. 10, the reflective film B1 may be patterned by a lift-off technique. Specifically, a photoresist W4 may be formed and patterned in advance to serve as a template. On the photoresist W4 and in a portion in which the photoresist W4 is not formed, the reflective film B1 may be formed, and the photoresist W4 may be removed. Thus, the reflective film B1 may be patterned.

At the step of forming the insulating layer D1 (Step S50), the insulating layer D1 may be formed by vapor deposition or sputtering. In forming the insulating layer D1, as illustrated in FIG. 8, the insulating layer D1 may be patterned using a mask W2. Alternatively, the insulating layer D1 may be patterned by a lift-off technique.

At the step of forming the first functional layer F1 (Step S60), the first functional layer F1 is formed to have: the first portion P1, PA positioned above the bank BK; and the second portion P2 positioned above the bank BK and outside the first portion P1, PA of the first functional layer F1. The second portion P2 is thicker than the first portion P1, PA.

As illustrated in FIG. 11, at the step of forming the first functional layer F1 (Step S60), the first functional layer F1 may be patterned by a lift-off technique. Specifically, a photoresist W5 having a first end face G1 is formed above the bank BK and in a portion in which the first light reflective layer R1 is not formed. On the photoresist W5 and in the portion in which the photoresist W5 is not formed, a third film M3 containing a material of the first functional layer F1 is formed. After the third film M3 is formed, the photoresist W5 may be removed so that a second end face G2 may be formed at a position not overlapping with the first light reflective layer R1 in a plan view. The second end face G2 serves as the end face EF of the second portion P2.

Alternatively, the first functional layer F1 may be formed by ink-jet printing. The first functional layer F1 may have an end portion formed thick by surface tension. The end portion is formed by, for example, what is referred to as the coffee ring effect.

### Second Embodiment

Another embodiment of the present disclosure will be described below. Note that, for convenience in description, like reference signs designate members having identical functions between this embodiment and the above embodiment. These members will not be elaborated upon repeatedly.

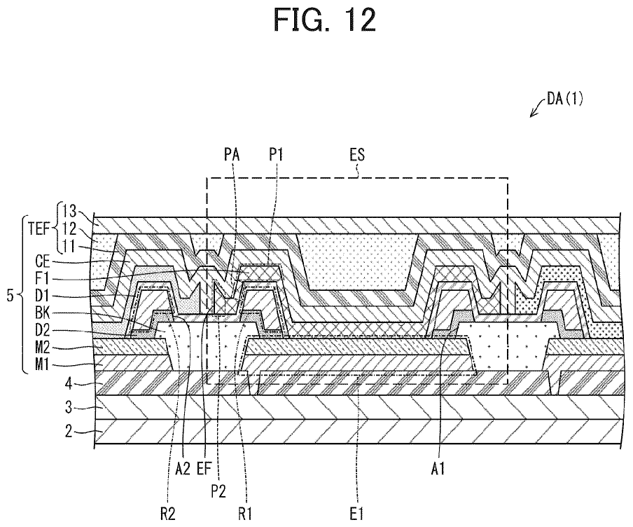

FIG. 12 is a cross-sectional view illustrating an exemplary configuration of the display device according to an embodiment of the present disclosure. As illustrated in FIG. 12, the electrode E1 may be out of contact with, and electrically separated from, the first light reflective layer R1. The electrode E1 may be formed of a layer separate from the first light reflective layer R1. The first light reflective layer R1 is separated from the electrode E1. Such a feature can reduce leakage of a current between adjacent light-emitting elements ES; that is, the “lateral current leakage”.

The light-emitting element ES may further include an insulating layer D2 positioned between the first light reflective layer R1 and the electrode E1. The insulating layer D2 may be an inorganic insulating layer containing an inorganic insulator such as silicon oxide and silicon nitride. The insulating layer D2 can insulate the first light reflective layer R1 from the electrode E1. The light-emitting element ES may further include an inorganic film 11 positioned between the counter electrode CE and the first photorefractive layer 12. The inorganic film 11 can protect the counter electrodes CE when the first photorefractive layer 12 is formed.

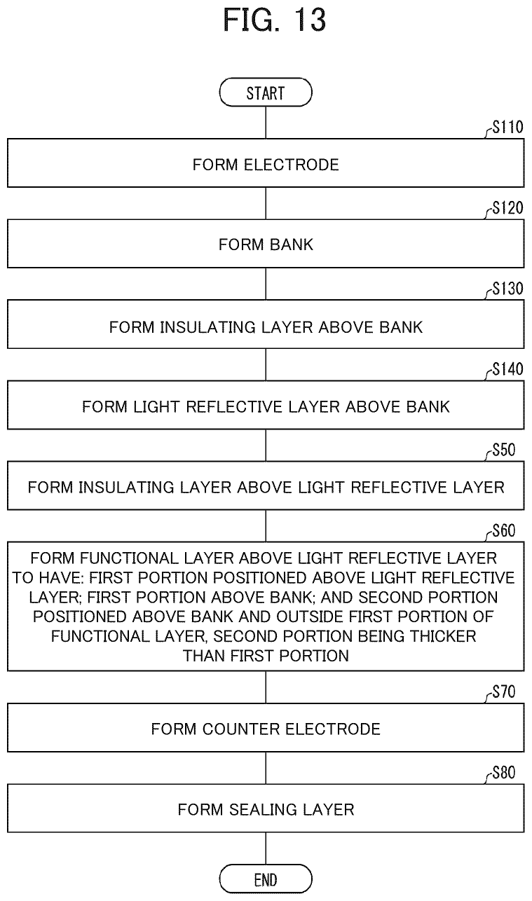

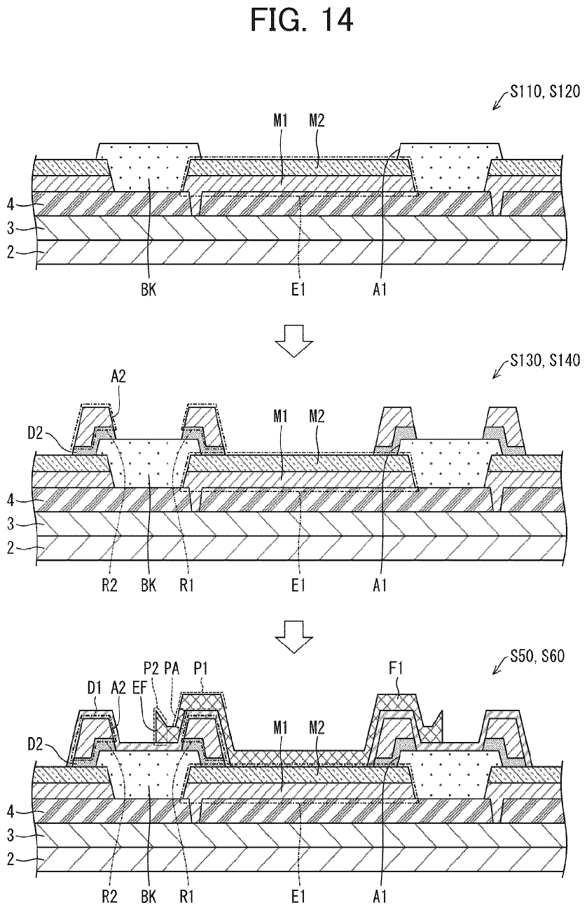

FIG. 13 is a flowchart showing an exemplary method for producing the light-emitting element illustrated in FIG. 12. FIG. 14 illustrates cross-sectional views showing an exemplary method for producing the light-emitting element illustrated in FIG. 12. As illustrated in FIGS. 13 and 14, the electrode E1 is formed on the planarization film 4 (Step S110). On the planarization film 4, the bank BK is formed (Step S120). Subsequently, the insulating layer D2 is formed above the bank BK (Step S130). The first light reflective layer R1 is formed above the bank BK (Step S140). Then, Steps S50, S60, S70, and S80 are carried out.

### Third Embodiment

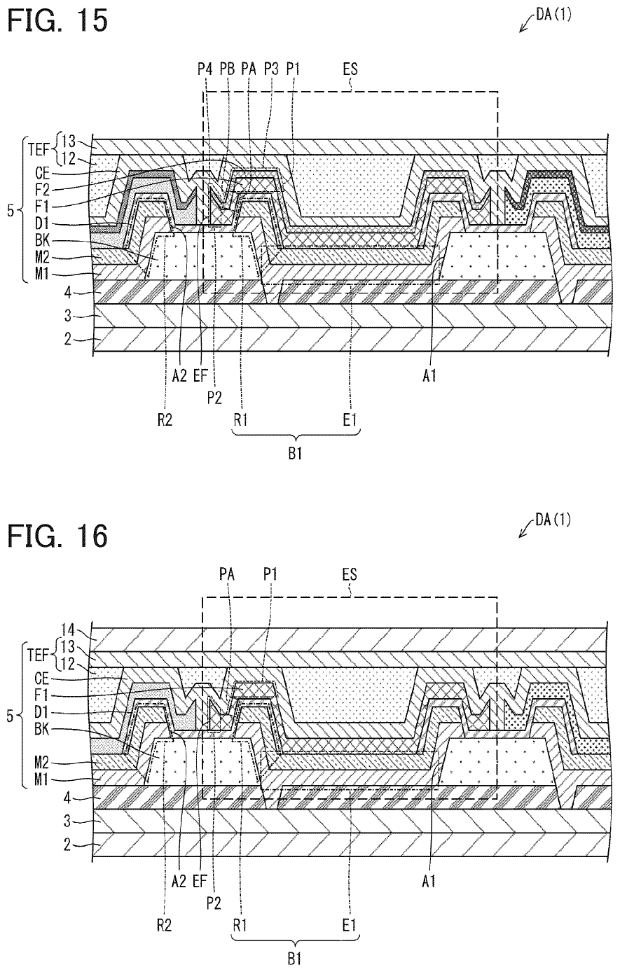

FIG. 15 is a cross-sectional view illustrating an exemplary configuration of the display device according to an embodiment of the present disclosure. As illustrated in FIG. 15, the light-emitting element ES may include a second functional layer F2 having: a third portion P3, PB positioned above the first portion P1, PA; and a fourth portion P4 positioned above the second portion P2. The second functional layer F2 may be, for example, any of a hole injection layer, a hole transport layer, an electron-shielding layer, a light-emitting layer, a hole-shielding layer, an electron transport layer, and an electron injection layer. When the first functional layer F1 is a light-emitting layer, the second functional layer F2 may be a light-emitting layer a color of which is the same as, or a different from, a color of the first functional layer F1.

The second functional layer F2 may be positioned directly above, and in contact with, the first functional layer F1. The second functional layer F2 may be patterned at the same step as, and into the same shape as, the first functional layer F1. The fourth portion P4 may have an end face overlapping with an end face EF of the second portion P2 in a plan view. One or more functional layers other than the second functional layer F2 may be patterned at the same step as, and into the same shape as, the first functional layer F1. An end face of each of the functional layers may overlap with the end face EF of the first functional layer F1 in a plan view.

According to this embodiment, the first functional layer F1 and the second functional layer F2 are patterned at the same step, thereby successfully reducing the number of steps. The second portion P2 and the fourth portion P4 are positioned in a recess formed between the upper face of the bank BK and the end face of the first light reflective layer R1. Hence, the fourth portion P4 is less likely to peel off, and a layer above the second functional layer F2 is less likely to deform.

### Fourth Embodiment

FIG. 16 is a cross-sectional view illustrating an exemplary configuration of the display device according to an embodiment of the present disclosure. As illustrated in FIG. 16, the light-emitting element ES includes: the first photorefractive layer 12; and a second photorefractive layer 14 positioned above the first photorefractive layer 12. A refractive index of the second photorefractive layer 14 may be smaller than a refractive index of the first photorefractive layer. The second photorefractive layer 14 may be in direct contact with the first photorefractive layer 12. A difference in refractive index between the first photorefractive layer 12 and the second photorefractive layer 14 increases a reflectance of light traveling from the first photorefractive layer 12 and incident on the second photorefractive layer 14.

### Fifth Embodiment

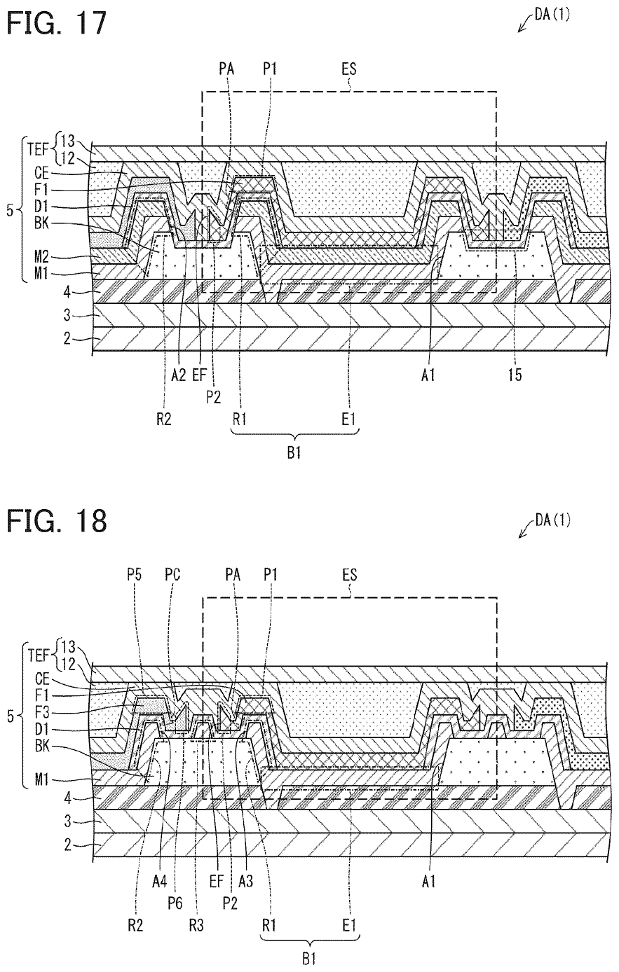

FIG. 17 is a cross-sectional view illustrating an exemplary configuration of the display device according to an embodiment of the present disclosure. As illustrated in FIG. 17, the bank BK may have an upper face provided with a recess portion 15, and, in a plan view, the second portion P2 and the recess portion 15 may overlap with each other. Thanks to such a feature, even if the first light reflective layer R1 is thin, the second portion P2 is less likely to peel off, and a layer above the first functional layer F1 is less likely to deform. Hence, the feature makes it possible to reduce costs of the first light reflective layer R1 and to provide the first light reflective layer R1 with a higher degree of flexibility in thickness.

The light-emitting element ES according to this embodiment includes: the bank BK having an upper face provided with the recess portion 15; the first light reflective layer R1 positioned above the bank BK; and the first functional layer F1 positioned above the first light reflective layer R1. The first functional layer F1 has: the first portion P1, PA positioned above the bank BK; and the second portion P2 positioned above the bank BK and outside the first portion of the first functional layer F1. The second portion P2 is thicker than the first portion P1, PA. In a plan view, the second portion P2 and the recess portion 15 overlap with each other.

A method for producing the light-emitting element ES according to this embodiment includes: a step of forming the bank BK having an upper face provided with the recess portion 15; a step of forming the first light reflective layer R1 above the bank BK; and a step of forming the first functional layer F1 above the first light reflective layer R1. At the step of forming the first functional layer F1, the first functional layer F1 is formed to have: the first portion P1, PA positioned above the bank BK; and the second portion P2 positioned above the bank BK and outside the first portion P1, PA of the first functional layer F1. The second portion P2 is thicker than the first portion P1, PA. In a plan view, the second portion P2 and the recess portion 15 overlap with each other.

### Sixth Embodiment

FIG. 18 is a cross-sectional view illustrating an exemplary configuration of the display device according to an embodiment of the present disclosure. As illustrated in FIG. 18, the display device 1 may include: the second light reflective layer R2 positioned above the bank BK; a third light reflective layer R3 positioned above the bank BK, and a third functional layer F3 positioned above the second light reflective layer R2. The third functional layer F3 may have: a fifth portion P5, PC positioned above the bank BK; and a sixth portion P6 positioned above the bank BK and outside the fifth portion of the third functional layer F3. The sixth portion P6 may be thicker than the fifth portion P5, PC. The fifth portion P5, PC may include: a fifth portion P5 positioned above the second light reflective layer R2; and a fifth portion PC positioned outside the second light reflective layer R2 of the second functional layer F2. The sixth portion P6 is thicker than one of, or both, the fifth portion P5 and the fifth portion PC.

The first light reflective layer R1 and the third light reflective layer R3 form a third opening A3. The third light reflective layer R3 and the second light reflective layer R2 form a fourth opening A4. In a plan view, the second portion P2 and the third opening A3 overlap with each other, and the sixth portion P6 and the fourth opening A4 overlap with each other.

According to this embodiment, an end portion of one functional layer is positioned inside one opening. Hence, unlike a case where ends of two or more functional layers are positioned within one opening, this embodiment may ignore a case where ends of two or more functional layers overlap with each other. Thus, this embodiment makes it possible to form the third opening A3 and the fourth opening A4 to have a relatively shallow depth so that a layer below the first functional layer F1 and the third functional layer F3 can be formed flat. As a result, when the first functional layer F1 and the third functional layer F3 are formed, and when a layer above the first functional layer F1 and the third functional layer F3 is formed, the layers can be applied more suitably and produced more efficiently.

### Seventh Embodiment

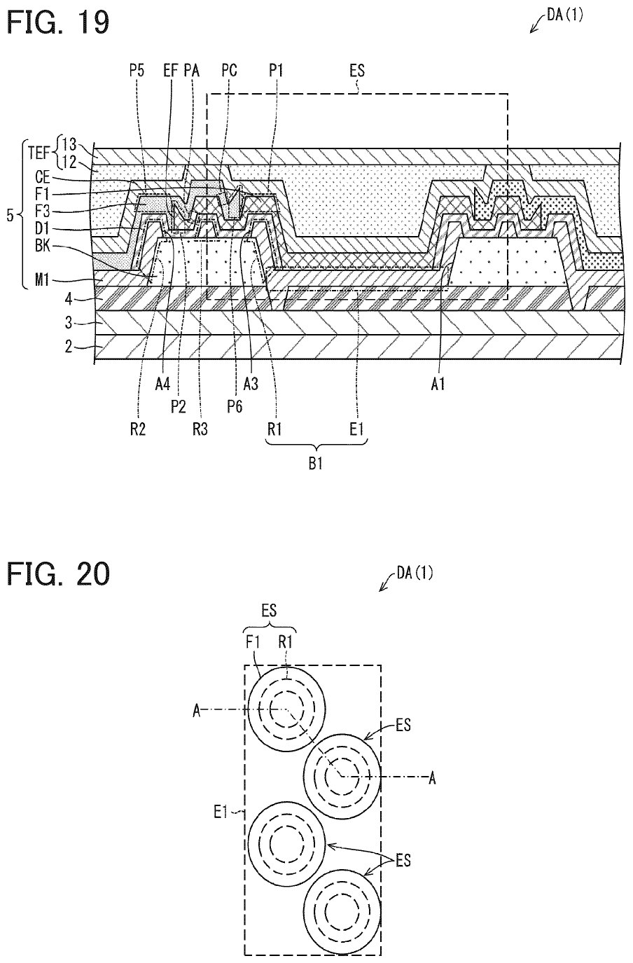

FIG. 19 is a cross-sectional view illustrating an exemplary configuration of the display device according to an embodiment of the present disclosure. As illustrated in FIG. 19, the display device 1 may include: the second light reflective layer R2 positioned above the bank BK; a third light reflective layer R3 positioned above the bank BK; and a third functional layer F3 positioned above the second light reflective layer R2. The third functional layer F3 may have: the fifth portion P5, PC positioned above the second light reflective layer R2; and the sixth portion P6 positioned above the bank BK and outside the fifth portion of the third functional layer F3. The sixth portion P6 may be thicker than the fifth portion P5, PC.

The first light reflective layer R1 and the third light reflective layer R3 form the third opening A3. The third light reflective layer R3 and the second light reflective layer R2 form the fourth opening A4. In a plan view, the second portion P2 and the fourth opening A4 overlap with each other, and the sixth portion P6 and the third opening A3 overlap with each other.

This embodiment makes it possible to form the third opening A3 and the fourth opening A4 to have a shallow depth because of the same reason described in the sixth embodiment. Furthermore, this embodiment makes it possible to form the first functional layer F1 and the third functional layer F3 to have a larger area than that of the first functional layer F1 and the third functional layer F3 of the sixth embodiment. If the lift-off technique is used to pattern a functional layer, a material of the functional layer is applied more readily to an opening of the template as the opening is larger. Hence, the third opening A3 and the fourth opening A4 can be formed to have a shallower depth. As a result, a layer below can be formed flatter and produced more efficiently.

### Eighth Embodiment

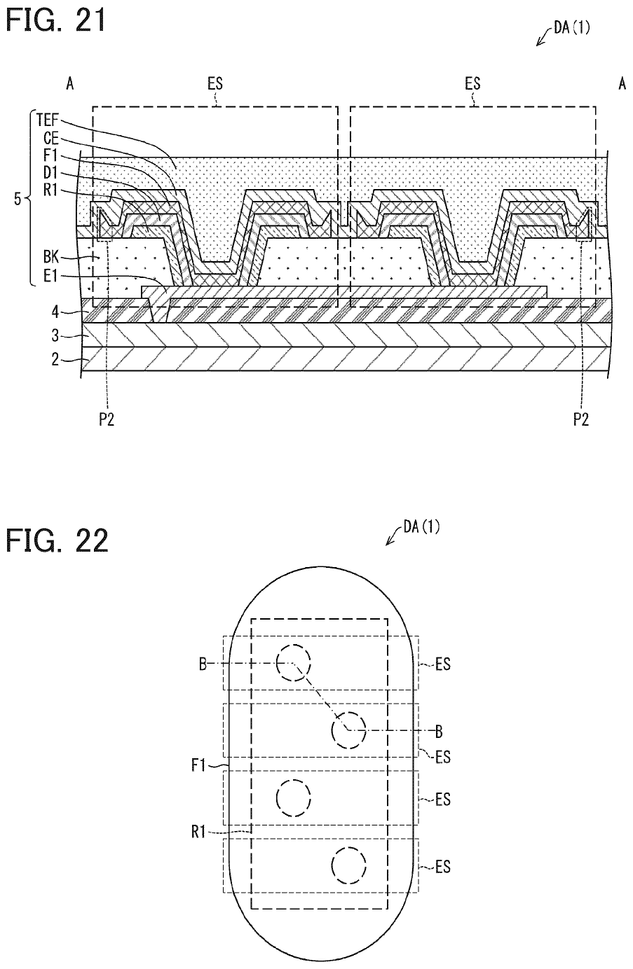

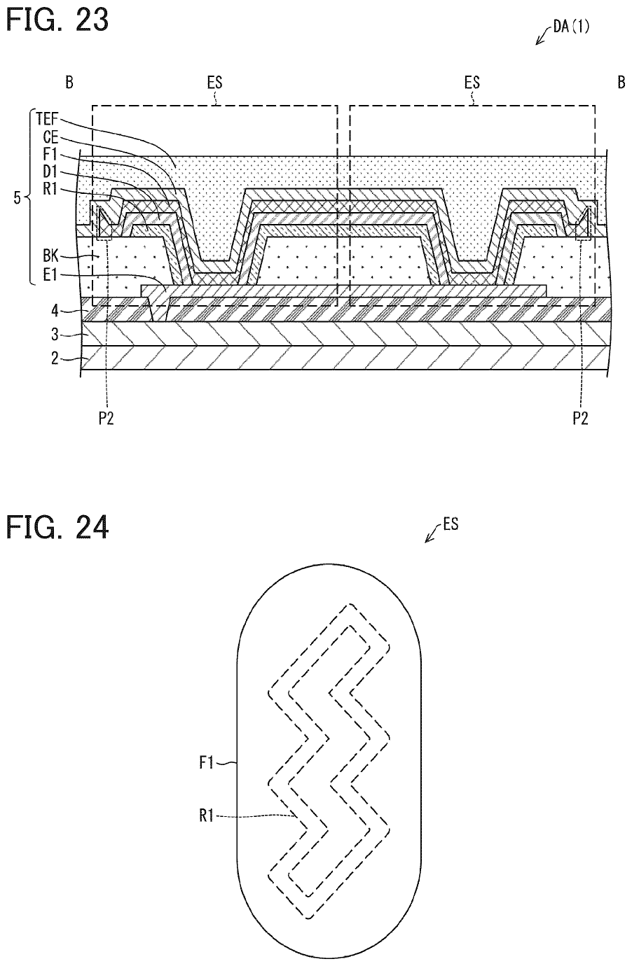

FIG. 20 is a plan view illustrating an exemplary configuration of the display device according to an embodiment of the present disclosure. FIG. 21 is a cross-sectional view taken along line A-A of FIG. 20. As illustrated in FIGS. 20 and 21, the display device 1 may include a plurality of the light-emitting elements ES for one pixel. When one pixel is provided with a plurality of light-emitting elements ES, each of the light-emitting elements ES can be formed small, and the first light reflective layer R1 can be formed to have a large area per light emission area. The plurality of light-emitting elements ES may be provided in any given number, shaped into any given shape, and arranged in any given manner.
FIG. 22 is a plan view illustrating a modification of a configuration of the display device according to an embodiment of the present disclosure. FIG. 23 is a cross-sectional view taken along line B-B of FIG. 22. As illustrated in FIGS. 22 and 23, for each of the pixels, the plurality of light-emitting elements ES has a plurality of the first functional layers F1 formed into a single piece. Furthermore, other constituent elements such as electrodes El and insulating layers D1 may also be formed into a single piece for each of the pixels. In other words, the plurality of light-emitting elements ES that belongs to the same pixel may share one or more constituent elements.
FIG. 24 is a plan view illustrating a modification of a configuration of the display device according to an embodiment of the present disclosure. As illustrated in FIG. 24, the display device 1 includes, for one pixel, a light-emitting element ES elongated in a plan view. Thanks to such a feature, the first light reflective layer R1 can be formed to have a large area per light emission area. The light-emitting element ES may have a bellows shape or a spiral shape.

The present disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the present disclosure. Moreover, the technical aspects disclosed in each embodiment may be combined together to achieve a new technical feature. For example, the recess portion 15 of the fifth embodiment may be provided to the upper face of the bank BK according to the first to fourth and the sixth to eighth embodiments. In a plan view, the second portion P2 and the recess portion 15 may overlap with each other.

1. A light-emitting element, comprising:
a bank;
a first light reflective layer positioned above the bank; and
a first functional layer positioned above the first reflective layer,
wherein the first functional layer has:
a first portion; and
a second portion positioned outside the first portion of the first functional layer,
the second portion being thicker than the first portion.

2. The light-emitting element according to claim 1,
wherein the first portion and the second portion are positioned above the bank.

3. The light-emitting element according to claim 1 or 2,
wherein the second portion projects upwards with respect to the first portion.

4. The light-emitting element according to any one of claims 1 to 3,
wherein, in a plan view, the second portion has an end face not overlapping with the first light reflective layer.

5. The light-emitting element according to any one of claims 1 to 4,
wherein the first functional layer includes a light-emitting layer.

6. The light-emitting element according to claim 5,
wherein the light-emitting layer contains a plurality of quantum dots and an inorganic matrix holding the plurality of quantum dots.

7. The light-emitting element according to any one of claims 1 to 6,
wherein the bank has an upper face provided with a recess portion, and
in a plan view, the second portion and the recess portion overlap with each other.

8. The light-emitting element according to any one of claims 1 to 7, further comprising:
a first opening formed in the bank; and
an electrode overlapping with the first opening in a plan view.

9. The light-emitting element according to claim 8,
wherein the electrode is in contact with the first light reflective layer.

10. The light-emitting element according to claim 8,
wherein the electrode is out of contact with the first light reflective layer.

11. The light-emitting element according to claim 8, further comprising
one reflective film including the electrode and the first light reflective layer.

12. The light-emitting element according to any one of claims 8 to 11,
wherein at least one of the first light reflective layer or the electrode includes: a first film reflective to light; and a second film positioned above the first film and transparent to light.

13. The light-emitting element according to any one of claims 1 to 12,
wherein, in a plan view, an outer shape of the first light reflective layer is similar to an outer shape of the first functional layer.

14. The light-emitting element according to any one of claims 1 to 13,
wherein, in a plan view, the first light reflective layer is shaped to surround a portion of the first functional layer.

15. The light-emitting element according to any one of claims 1 to 13,
wherein, in a plan view, the first light reflective layer is shaped not to surround the first functional layer.

16. The light-emitting element according to any one of claims 1 to 15,
wherein, in a plan view, the first light reflective layer is shaped into a bellows shape.

17. The light-emitting element according to any one of claims 1 to 16, further comprising
a second functional layer having: a third portion positioned above the first portion; and
a fourth portion positioned above the second portion.

18. The light-emitting element according to any one of claims 1 to 17, further comprising
a first photorefractive layer positioned above the first functional layer.

19. The light-emitting element according to claim 18, further comprising
a second photorefractive layer positioned above the first photorefractive layer,
wherein a refractive index of the second photorefractive layer is smaller than a refractive index of the first photorefractive layer.

20. The light-emitting element according to claim 18 or 19,
wherein, in a plan view, the first photorefractive layer does not overlap with at least a portion of an upper face of the bank.

21. A display device comprising the light-emitting element according to any one of claims 1 to 20.

22. The display device according to claim 21, further comprising
a second light reflective layer positioned above the bank,
wherein the first light reflective layer and the second light reflective layer form a second opening, and
in a plan view, the second portion and the second opening overlap with each other.

23. The display device according to claim 21, further comprising
a second light reflective layer positioned above the bank;
a third light reflective layer positioned above the bank; and
a third functional layer positioned above the second light reflective layer,
wherein the third functional layer has:
a fifth portion positioned above the bank; and
a sixth portion positioned above the bank and outside the fifth portion of the
third functional layer, the sixth portion being thicker than the fifth portion,
the first light reflective layer and the third light reflective layer form a third opening,
the third light reflective layer and the second light reflective layer form a fourth opening, and
in a plan view, the second portion and the third opening overlap with each other, and the sixth portion and the fourth opening overlap with each other.

24. The display device according to claim 21, further comprising
a second light reflective layer positioned above the bank;
a third light reflective layer positioned above the bank; and
a third functional layer positioned above the second light reflective layer,
wherein the third functional layer has:
a fifth portion positioned above the bank; and
a sixth portion positioned above the bank and outside the fifth portion of the third functional layer, the sixth portion being thicker than the fifth portion,
the first light reflective layer and the third light reflective layer form a third opening,
the third light reflective layer and the second light reflective layer form a fourth opening,
in a plan view, the second portion and the fourth opening overlap with each other, and the sixth portion and the third opening overlap with each other, and
between the third opening and the fourth opening, the first functional layer and the third functional layer overlap with each other.

25. A display device comprising a plurality of the light-emitting elements according to any one of claims 1 to 20.

26. The display device according to claim 25,
wherein, for each of pixels of the display device, the plurality of light-emitting elements has a plurality of the first functional layers formed into a single piece.

27. A method for producing a light-emitting element, the method comprising:
a step of forming a bank;
a step of forming a light reflective layer above the bank; and
a step of forming a functional layer above the light reflective layer,
wherein, at the step of forming the functional layer, the first functional layer is formed to have: a first portion; and a second portion positioned outside the first portion of the first functional layer, the second portion being thicker than the first portion.

28. The method for producing the light-emitting element according to claim 27,
wherein the step of forming the functional layer includes:
forming a photoresist above the bank and in a portion in which the light reflective layer is not formed, the photoresist having a first end face; and
forming, in a portion in which the photoresist is not formed, a third film containing a material of the functional layer, and, after the third film is formed, removing the photoresist so that a second end face is formed at a position not overlapping with the light reflective layer in a plan view, the second end face serving as an end face of the second portion.
